(19) United States
(12) Patent Application Publication
(10) Pub. No.: US 2013/0196539 A1
(43) Pub. Date: Aug. 1, 2013

(54) Electronics Packaging Assembly with Dielectric Cover

(71) Applicant: John Mezzalingua Associates, Inc., East Syracuse, NY (US)

(72) Inventors: Steven K. SHAFER, Chittenango, NY (US); William WITKOWSKI, Marcellus, NY (US)

(73) Assignee: John Mezzalingua Associates, Inc., East Syracuse, NY (US)

(21) Appl. No.: 13/739,844

(22) Filed: Jan. 11, 2013

Related U.S. Application Data
(60) Provisional application No. 61/585,902, filed on Jan. 12, 2012.

(51) Int. Cl. H05K 5/06; H01R 9/05

(52) U.S. Cl. CPC H05K 5/06; H01R 9/05
USPC 439/578; 361/752

(57) ABSTRACT

An electronics package assembly includes a housing having an opening and defining an internal cavity. The electronic package assembly further includes a printed circuit board assembly sealing and covering the opening of the housing, the printed circuit board assembly having an internal side facing the internal cavity and an opposing external side. The printed circuit board assembly includes a dielectric substrate and a conductive layer bonded to the dielectric substrate. The printed circuit board assembly further includes a surface-mounted electronic device electromechanically coupled to the conductive layer, the surface-mounted device positioned within the internal cavity of the housing.

### CROSS-REFERENCE TO RELATED APPLICATIONS

This application claims priority to U.S. Provisional Application No. 61/585,902 filed Jan. 12, 2012, and entitled ELECTRONICS PACKAGING ASSEMBLY WITH DIELECTRIC COVER.”

### FIELD OF TECHNOLOGY

This disclosure relates generally to a packaging assembly for protecting electronic components and, more specifically, to a printed circuit board assembly that operates as a cover for a packaging assembly housing.

### BACKGROUND

A conventional electronics package assembly such as a coaxial splitter typically includes a metallic housing and sealed cover. The housing accommodates the internal electronics, and the cover seals the electronics from exposure to external environmental elements such as moisture and dirt. In almost all constructions, the internal electronics include a printed circuit board assembly comprising a printed circuit board and electronic components. The printed circuit board is fabricated of a non-conductive substrate such as fiberglass, and mechanically supports and electrically connects the electronic components using conductive pathways or signal traces etched from copper sheets that are laminated onto the substrate.

In some printed circuit board assemblies, known as through-hole construction, the electronic components have electrical lead wires which are inserted through conductive holes or vias in the substrate. Thus, the electronic component is located on one side of the printed circuit board, and the leads are soldered to the conductive pathways or signal traces on the opposing side of the board.

In other printed circuit board assemblies, known as surface-mount construction, newer manufacturing techniques have allowed the electronic components to be mounted to conductive pads on the same side of the board as the conductive pathways. The advantage of this type of construction is that the opposing side of the substrate may be fully utilized, which may reduce the number of substrate layers required for the assembly.

In both types of constructions, the printed circuit board assemblies are often secured to the housing with screws, but positioned away from the internal surfaces of the housing, including the cover, to prevent the conductive pathways or traces from contacting the metallic surfaces of the housing or cover. Typically, a standoff is utilized to provide the separation. The standoff may be provided in the shank of the screw or by a raised lug on the housing internal surface.

### SUMMARY

Although current printed circuit board assemblies can be useful and may be advantageous for certain applications, they can be improved. Disclosed herein is a printed circuit board assembly having surface-mounted devices in which the unpopulated side functions as a cover.

In one embodiment, an electronics package assembly, comprises: a housing comprising side walls and a bottom wall, the housing defining an internal cavity for placement of electronic components; and a fluid-impermeable cover sealed to a top of the housing, the cover comprising a printed circuit board assembly having an internal side and an opposing external side, the printed circuit board assembly comprising: a first dielectric substrate having a first side and an opposing second side; a first conductive layer bonded to the first side of the first dielectric substrate; and a surface-mounted electronic device electromechanically coupled to the first conductive layer, the surface-mounted device positioned within the internal cavity of the housing.

In another embodiment, a coaxial connector assembly, comprises: an electrically conductive housing defining an internal cavity for enclosing electronic devices, the housing comprising a grounding element; a coaxial input element coupled to the housing; a first coaxial output element coupled to the housing; an electrically conductive bridge coupled to the housing; and a fluid-impermeable cover coupled to the conductive bridge, the cover comprising a printed circuit board assembly having an internal side and an opposing external side, the printed circuit board assembly comprising: a first dielectric substrate having a first side and an opposing second side; a first electrically conductive layer bonded to the first side of the first dielectric substrate, the first conductive layer providing a first electrically conductive pathway from the coaxial input element to the first coaxial output element, and further providing a second electrically conductive pathway to the conductive bridge; and a surface-mounted electronic device electromechanically coupled to the first electrically conductive layer, the surface-mounted device positioned within the internal cavity of the housing.

In another embodiment an electronics package assembly comprises: a housing having an opening and defining an internal cavity; and a printed circuit board assembly sealing and covering the opening of the housing, the printed circuit board assembly having an internal side facing the internal cavity and an opposing external side, the printed circuit board assembly including: a dielectric substrate; a conductive layer bonded to the dielectric substrate; and a surface-mounted electronic device electromechanically coupled to the conductive layer, the surface-mounted device positioned within the internal cavity of the housing.

### BRIEF DESCRIPTION OF THE DRAWINGS

The features described herein can be better understood with reference to the drawings described below. The drawings are not necessarily to scale, emphasis instead generally being placed upon illustrating the principles of the invention. In the drawings, like numerals are used to indicate like parts throughout the various views.

FIG. 1 depicts an exploded perspective view of an electronics package assembly according to one embodiment;

FIG. 2 depicts a partial cross-sectional view of the electronics package assembly of FIG. 1;

FIG. 3 depicts a cutaway cross-sectional view of an electronics package assembly according to another embodiment;

FIG. 4 depicts a cutaway cross-sectional view of an electronics package assembly according to yet another embodiment;

FIG. 5 depicts an exploded perspective view of an electronics package assembly according to another embodiment;

FIG. 6A depicts a plan view of a first side of the cover in the electronics package assembly shown in FIG. 5; and

FIG. 6B depicts a plan view of an opposing second side of the cover in the electronics package assembly shown in FIG. 5.

### DETAILED DESCRIPTION

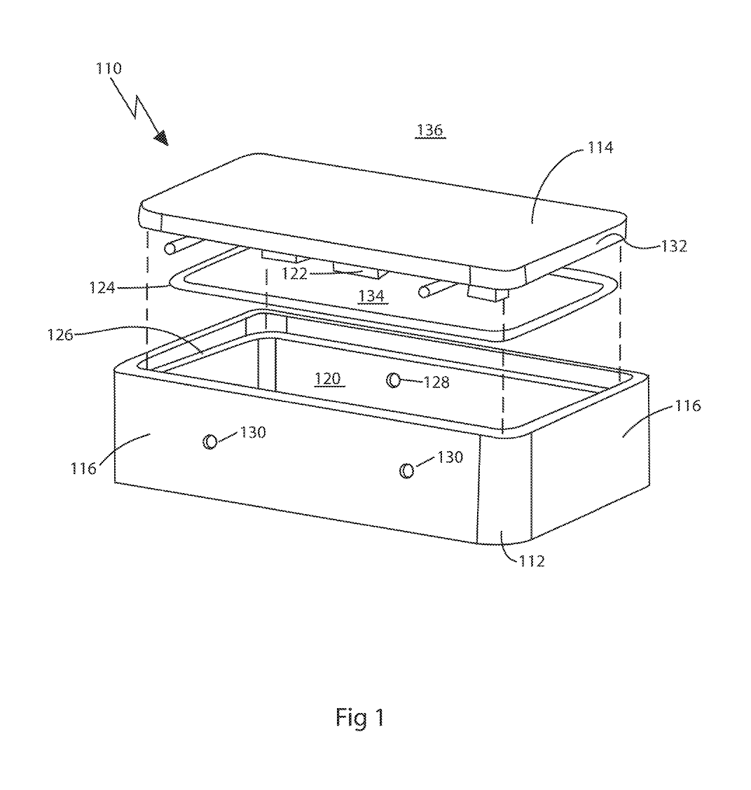

Referring to FIG. 1, an electronics package assembly 110 includes a housing 112 and a cover 114. In one embodiment, the housing 112 is rectangular in shape, having four side walls 116 joined to a bottom plate (not shown). Other geometries are contemplated to suit the particular application. For example, the housing 112 may be circular and thus include a single side wall 116. Together, the side walls 116 and the bottom plate define an internal cavity 120 of the housing 112 into which electronic components 122 are positioned. The cover 114 is adapted to snugly fit or nest in the housing 112 to protect the electronic components 122 from exposure to external environmental elements such as moisture and dirt. In this regard, a seal 124 may be positioned between the internal cavity 120 and the housing 112. In one embodiment, the housing 112 includes an inner ledge 126 into which the cover 114 may seat. The seal 124 may be positioned between the side walls 116 and the side edge of the cover 114, between the inner ledge 126 and the underside of the cover, or both. The housing 112 may further include provisions to route the internal electronics or wires from the internal cavity 120 to the outside environment. In the embodiment depicted in FIG. 1, an input element 128 provides a connection point or access for electrical wires entering the housing 112, and an output element 130 provides a connection point or egress for electrical wires exiting the housing. The input and output elements 128, 130 provide an electrical connection from points exterior of the housing 112 to the electronic components 122 within the housing. The input and output elements 128, 130 may be potted leads, electrical connectors, or the like.

The electronics package assembly 110 of the present disclosure eliminates the additional manufacturing steps or components typically required to position the circuit board within the internal cavity of the housing. Specifically, the printed circuit board is utilized as the cover to the housing. As illustrated in FIG. 1, the cover 114 comprises a printed circuit board assembly 132 having an internal side 134 and an opposing external side 136. The external side 136 of the printed circuit board assembly 132 is exposed to the outside environment. The internal side 134 of the printed circuit board assembly 132 includes the electronic components 122, which are sealed from the external environment by the seal 124. In one embodiment, the seal 124 is a rubber gasket such as an o-ring. In other embodiments, the seal 124 could be epoxy or similar glue. In still other embodiments, the seal 124 could be a solder compound.

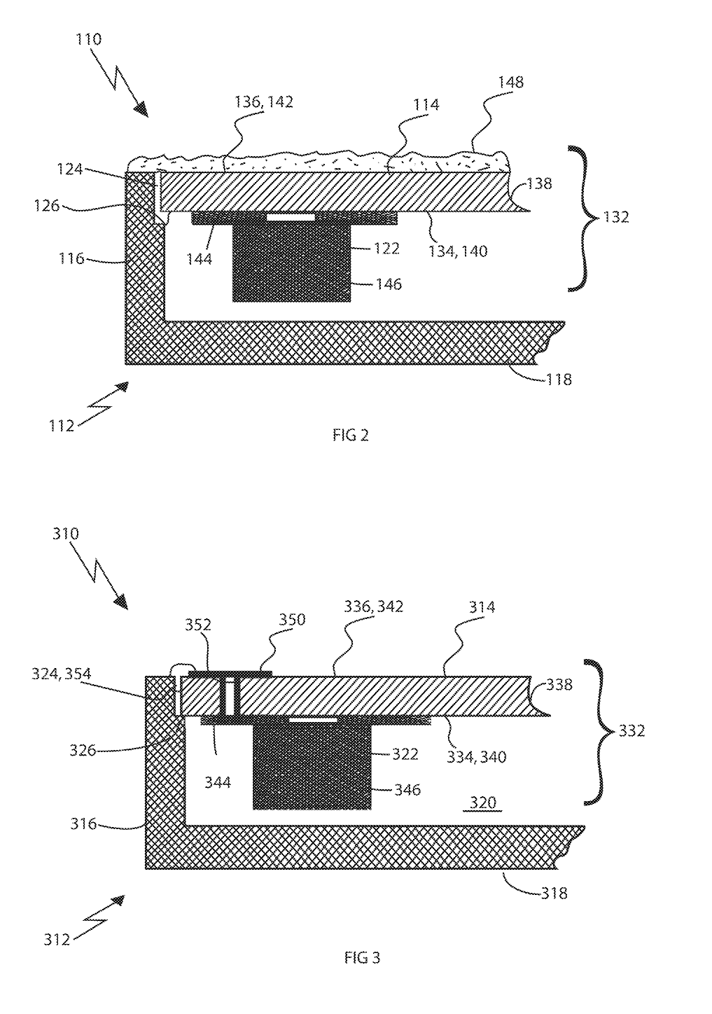

Referring to FIG. 2, wherein like numbers indicate like elements from FIG. 1, depicted is a partial cross-sectional view of the electronics package assembly 110 shown in FIG. 1. In the illustrated embodiment, the housing 112 is a unified structure comprising the bottom plate 118 and side walls 116, and is formed of an electrically conductive material such as steel. The side walls 116 include an inner ledge 126 to support the cover 114. The seal 124 between the cover 114 and the housing 112 is epoxy, as opposed to the o-ring depicted in FIG. 1. The cover 114 comprises a printed circuit board assembly 132 with an external side 136 exposed to the environment, and a protected internal side 134 facing the internal cavity 120. The printed circuit board assembly 132 includes a dielectric substrate 138 having a first side 140 and an opposing second side 142. In this particular embodiment, the first side 140 of the dielectric substrate 138 is the same surface as the internal side 134 of the printed circuit board assembly 132, and the second side 142 of the dielectric substrate 138 is the same surface as the external side 136 of the printed circuit board assembly. The dielectric substrate 138 may be formed of any conventional material or technique practiced in the printed circuit board industry. For example, the dielectric substrate 138 may comprise laminated layers of polytetrafluoroethylene (Teflon), woven glass and epoxy (FR-4, FR-5, G-10, CEM-3, CEM-4, CEM-5), phenolic cotton paper (FR-2), cotton paper and epoxy (FR-3, CEM-1, CEM-2), or matte glass and polyester (FR-6).

A conductive layer 144 is bonded to the first side 140 of the dielectric substrate 138. In one example, the conductive layer 144 is a thin copper foil. The copper foil is adapted to provide copper traces for the electrical signal pathways for the various electronic components 122. The copper foil is bonded over the entire first side 140 of the dielectric substrate 138, a temporary mask is applied to the foil to create and protect the desired signal traces, and the unmasked copper foil is removed by a chemical etchant such as ferric chloride, ammonium persulfate, or hydrochloric acid for example. The remaining copper traces provide the electrical signal pathways for the various electronic components 122. In another example, the conductive layer 144 is formed on the dielectric substrate 138 by electroplating.

The dielectric substrate 138 mechanically supports the electronic components 122. In one embodiment, the electronic components 122 are surface-mounted devices 146. As described briefly hereinabove, surface mount devices 146 are electronic components mounted directly onto the surface of the printed circuit board assembly 132, rather than the construction method of fitting components with wire leads into holes (vias) in the circuit board. Surface-mount components are usually smaller than their through-hole counterpart because the surface-mount device has either very small electrical lead wires, or no leads at all. The surface-mounted device 146 may have small metal tabs or end caps that are soldered directly on to the conductive layer 144 of the dielectric substrate 138, short pins or leads of various styles, flat contacts, a matrix of solder balls (BGAs), or terminations on the body of the component.

One important aspect of the cover 114 is that it is formed of fluid-impermeable materials to prevent ingress of moisture, such as water or humid air, through the cover into the internal cavity 120 of the housing 112. Failure to prevent moisture ingress could result in malfunction of the electronic components. The disclosed dielectric substrate 138 can be adapted to prevent moisture ingress with little or no modification. Many of the common substrate materials used in the manufacture of printed circuit boards are resistant to moisture break-through. Further, in those embodiments wherein the electronic components 122 comprise surface-mounted devices 146, there are no vias or through-holes to create potential leak paths. In other embodiments wherein the printed circuit board assembly 132 does include through-hole construction, a fluid-impermeable cover 114 may be provided by filling the vias with solder, for example. In other embodiments, a fluid-impermeable conformal coating 148 may be applied over the external side 136 of the dielectric substrate 138. The conformal coating 148 may be dipped, sprayed, or sputtered in a vacuum. Exemplary materials for the conformal coating 148 include wax, silicone rubber, polyurethane, acrylic, or epoxy.

Referring now to FIG. 3, depicted is a cross-sectional side view of an electronics package assembly 310 according to another embodiment of the present invention. The assembly 310 has practical application when the internal electronics require a ground path through the housing 312, for example in a connector for a coaxial cable that requires connection to an external grounding lug or block. The electronics package assembly 310 includes a unified housing 312 comprising a bottom plate 318 and side walls 316, and is formed of a conductive material such as steel. The side walls 316 include an inner ledge 326 to support a cover 314.

The cover 314 comprises a printed circuit board assembly 332 having an internal side 334 and an opposing external side 336 exposed to the outside environment. The printed circuit board assembly 332 includes a dielectric substrate 338 having a first side 340 and an opposing second side 342. In this particular embodiment, the first side 340 of the dielectric substrate 338 is the same surface as the internal side 334 of the printed circuit board assembly 332, and the second side 342 of the dielectric substrate 338 is the same surface as the external side 336 of the printed circuit board assembly. The dielectric substrate 338 may be formed of any conventional material or technique practiced in the printed circuit board industry. For example, the dielectric substrate 338 may comprise laminated layers of polytetrafluoroethylene (Teflon), woven glass and epoxy (FR-4, FR-5, G-10, CEM-3, CEM-4, CEM-5), phenolic cotton paper (FR-2), cotton paper and epoxy (FR-3, CEM-1, CEM-2), or matte glass and polyester (FR-6).

The cover 314 is sealed to the housing 312 to prevent the ingress of moisture from the outside environment into the internal cavity 320. In one embodiment, the seal 324 is a rubber gasket such as an o-ring. In other embodiments, the seal 324 could be epoxy or similar glue. In the illustrated embodiment, the seal 324 is solder compound that forms a continuous bead around the perimeter of the first dielectric substrate 338.

A first conductive layer 344 is bonded to the first side 340 of the dielectric substrate 338. In one example, the first conductive layer 344 is a thin copper foil. The copper foil is adapted to provide copper traces for the electrical signal pathways for the various electronic components 322. In one example, the copper foil is bonded over the entire first side 340 of the dielectric substrate 338, a temporary mask is applied to the foil to create and protect the desired signal traces, and the unmasked copper foil is removed by a chemical etchant such as ferric chloride, ammonium persulfate, or hydrochloric acid. The remaining copper traces provide the electrical signal pathways for the various electronic components 322.

The dielectric substrate 338 mechanically supports the electronic components 322 mounted on the printed circuit board assembly 332. In one embodiment, the electronic components 322 are surface-mounted devices 346. As described above, surface mount devices 346 are electronic components mounted directly onto the surface of the printed circuit board assembly 332, rather than the construction method of fitting components with wire leads into holes (vias) in the circuit board. The surface-mounted devices 346 may have small metal tabs or end caps that are soldered directly on to the first conductive layer 344 of the dielectric substrate 338, short pins or leads of various styles, flat contacts, a matrix of solder balls (BGAs), or terminations on the body of the component.

The first dielectric substrate 338 further includes a second conductive layer 350 bonded to the second side 342 of the first dielectric substrate 338. In one example, the second conductive layer 350 is a thin copper foil similar to the first conductive layer 344, and provides a conductive pathway for the transmission of electrical signals. The second conductive layer 350 is connected to the first conductive layer 344 by a conductive pathway 352. In one example, the conductive pathway 352 is a via through the first dielectric substrate 338. The via 352 can be constructed by laser-drilling a hole through the first dielectric substrate 338 and electroplating the hole with copper, for example. In another example, the conductive pathway 352 can be formed from a rivet protruding through the substrate 338. The via 352 includes conductive pads (not shown) on the first side 340 and the second side 342 of the substrate 338, with the conductive pathway 352 joining them. The conductive pad on the first side 340 of the substrate 338 can connect to the first conductive layer 344, and the conductive pad on the second side 342 of the substrate 338 can connect to the second conductive pathway 352. In this manner, an electronic path is provided from the electronics in the internal cavity 320, such as the surface-mounted devices 346 to the second conductive layer 350 on the external side 336 of the electronics package assembly 310. In one example, the electronic path may be a path to electrical ground.

In some arrangements, it may be beneficial or desirous to link the electrical path on the cover 314 of the electronics package assembly 310 to the housing 312, such as would be the case when the housing 312 includes a grounding element. The electronics package assembly 310 may therefore include a conductive bridge 354 to provide the link. In one embodiment, wherein the housing 312 is formed of a conductive material such as steel, the conductive bridge 354 may be realized by copper jumper wires soldered on one end to the housing and on the other end to the conductive layer 350. In another embodiment, depicted in FIG. 3, the conductive bridge 354 is realized by the solder seal 324.

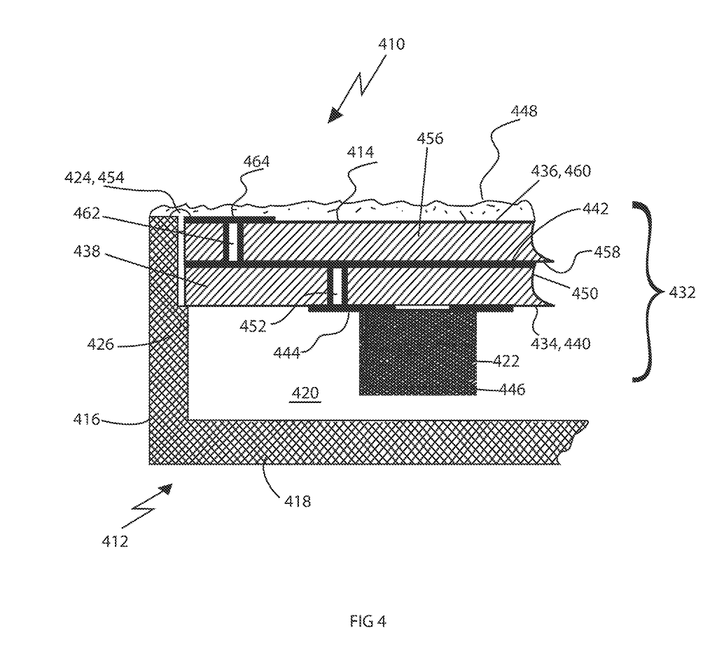

Turning now to FIG. 4, depicted is a cutaway cross-sectional view of an electronics package assembly 410 that includes a cover having more than one dielectric substrate. The electronics package assembly 410 includes a unified housing 412 comprising a bottom plate 418 and side walls 416, and is formed of a conductive material such as steel. The side walls 416 include an inner ledge 426 to support a cover 414.

The cover 414 is sealed to the housing 412 to prevent the ingress of moisture from the outside environment into an internal cavity 420. In one embodiment, a seal 424 is formed of solder compound that forms a continuous bead around the perimeter of the cover 414.

The cover 414 comprises a multilayer printed circuit board assembly 432 having an internal side 434 and an opposing external side 436 exposed to the outside environment. The multilayer printed circuit board assembly 432 includes a first dielectric substrate 438 and a second dielectric substrate 456. The first dielectric substrate 438 has a first side 440 and an opposing second side 442, and the first side 440 is the same surface as the internal side 434 of the printed circuit board assembly 432. The second dielectric substrate 456 has a first side 458 and an opposing second side 460, the second side 460 being the same surface as the external side 436 of the printed circuit board assembly 432. Both the first and second dielectric substrates 438, 456 may be formed of any conventional material or technique practiced in the printed circuit board industry. For example, the substrates 438, 456 may comprise laminated layers of polytetrafluoroethylene (Teflon), woven glass and epoxy (FR-4, FR-5, G-10, CEM-3, CEM-4, CEM-5), phenolic cotton paper (FR-2), cotton paper and epoxy (FR-3, CEM-1, CEM-2), or matte glass and polyester (FR-6).

A first conductive layer 444 is bonded to the first side 440 of the first dielectric substrate 438. In one example, the first conductive layer 444 is a thin copper foil. The copper foil is adapted to provide copper traces for the electrical signal pathways for the various electronic components within the internal cavity 420. In one example, the copper foil is bonded over the entire first side 440 of the first dielectric substrate 438, then a temporary mask is applied to the foil to create and protect the desired signal traces, and then the unmasked copper foil is removed by a chemical etchant such as ferric chloride, ammonium persulfate, or hydrochloric acid. The remaining copper traces provide the electrical signal pathways for the various electronic components.

The first dielectric substrate 438 mechanically supports the electronic components mounted on the printed circuit board assembly 432. In one embodiment, the electronic components are surface-mounted devices 446. As described above, surface mount devices 446 are electronic components mounted directly onto the surface of the printed circuit board assembly 432, rather than the construction method of fitting components with wire leads into holes in the circuit board. The surface-mounted devices 446 may have small metal tabs or end caps that are soldered directly on to the first conductive layer 444 of the first dielectric substrate 438, short pins or leads of various styles, flat contacts, a matrix of solder balls (BGAs), or terminations on the body of the component.

The printed circuit board assembly 432 further includes a second conductive layer 450 bonded to the second side 442 of the first dielectric substrate 438, or to the first side 458 of the second dielectric substrate 456. In one example, the second conductive layer 450 is a ground plane. The second conductive layer 450 can be formed from a thin copper foil similar to the first conductive layer 444 as described above, and provide a conductive pathway for the transmission of electrical signals. The second conductive layer 450 can be connected to the first conductive layer 444 by a first conductive pathway 452. In one example, the first conductive pathway 452 is a blind via extending from the first side 440 of the first dielectric substrate 438 to a surface of an internal substrate layer of the printed circuit board assembly 432, such as the second side 442 of the first dielectric substrate 438. The blind via 452 can be formed into the substrate layer 438 prior to the layers being bonded together. The blind via 452 may include conductive pads (not shown) on the first side 440 and the second side 442 of the substrate 438, with the conductive pathway 452 joining them. The conductive pad on the first side 440 of the substrate 438 can connect to the first conductive layer 444, and the conductive pad on the second side 442 of the substrate 438 can connect to the second conductive pathway 452. In this manner, an electronic path is provided from the electronics in the internal cavity 420, such as the electronic components 422 and the surface-mounted devices 446, to the second conductive layer 450 (e.g., ground plane) on the second dielectric substrate 456.

The second dielectric substrate 456 may include additional conductive paths or traces on the first side 458 of the substrate. These additional traces may provide electronic pathways for additional electronic components located on the first side 458, and may or may not connect to the second conductive layer 450.

The printed circuit board assembly 432 may further include a second conductive pathway 462, such as a via, extending through the second dielectric substrate 456. In one example, the second conductive pathway 462 is a blind via extending from the second side 460 of the substrate 456 to a surface of an internal substrate layer of the printed circuit board assembly 432, such as the second side 442 of the first dielectric substrate 438. A blind via is exposed on only one side of the circuit board substrate 438. In one embodiment, the second via 462 is connected to the second conductive layer 450. The blind via 462 can be formed into the substrate layer 456 prior to the layers being bonded together. The blind via 462 may include conductive pads (not shown) on the first side 458 and the second side 460 of the substrate 456, with the conductive pathway 462 joining them. The conductive pad on the first side 458 of the substrate 456 can connect to the second conductive layer 450, and the conductive pad on the second side 460 of the substrate 456 can connect to a third conductive layer 464, which may be a thin copper foil similar to the first conductive layer 444 and second conductive layer 450, and provide a conductive pathway for the transmission of electrical signals. The third conductive layer 464 may connect other electronic components on the second side 460 of the substrate 456 or may provide an external path to ground, as described below.

In some arrangements, it may be beneficial or desirous to link the electrical path on the cover 414 of the electronics package assembly 410 to the housing 412, such as would be the case when the housing 412 includes a grounding element. The electronics package assembly 410 may therefore include a conductive bridge 454 to provide the link. In one embodiment, wherein the housing 412 is formed of a conductive material such as steel, the conductive bridge 454 may be realized by copper jumper wires soldered on one end to the housing and on the other end to the third conductive layer 464. In another embodiment, depicted in FIG. 4, the conductive bridge 454 is realized by the solder seal 424 that is connected to the second conductive pathway 462 (or a conductive pad thereof). In this manner, an electronic path may be provided from the surface-mounted devices 446 in the internal cavity 420 to the housing 412. As described above with reference to FIG. 2, a fluid-impermeable conformal coating 448 may be applied over the external side 436 of the second dielectric substrate 456 to maintain a moisture-proof barrier.

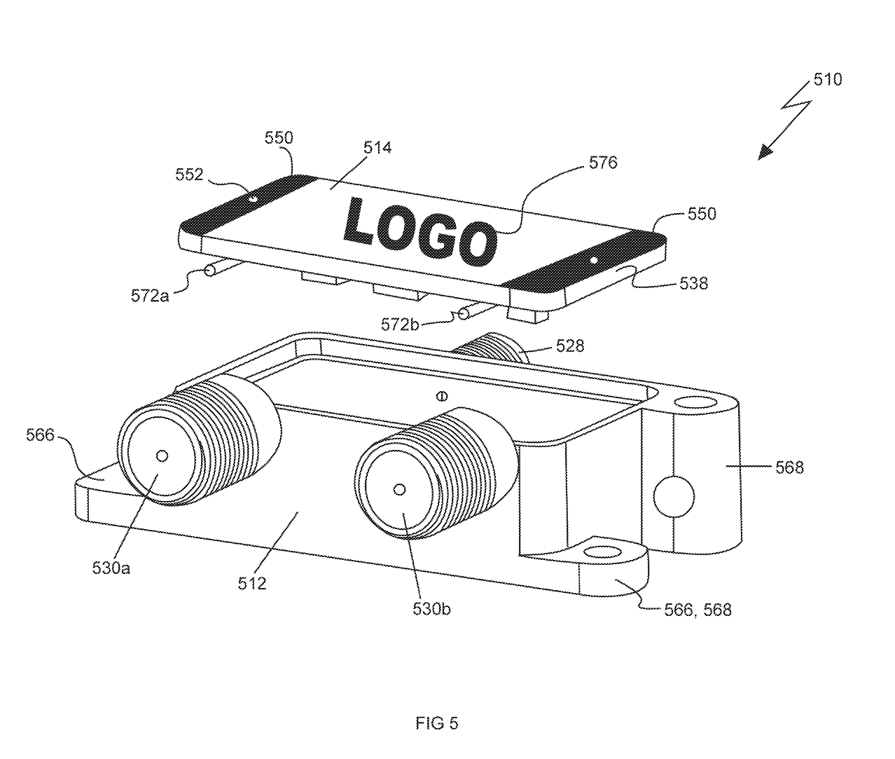

Turning now to FIG. 5, depicted is an exploded perspective view of an electronics package assembly 510 that is suitable for use as a coaxial cable splitter. In the disclosed embodiment, the package assembly 510 is a two-way splitter. The package assembly 510 includes a splitter housing 512 and a fluid-impermeable cover 514. The splitter housing 512 includes an input element or input port 528 and two output elements or distribution ports 530a and 530b. The ports 528, 530a, and 530b may be adapted for interface connection with coaxial connectors, such as F-type, BNC, RCA-type, or the like. The splitter 510 may be adapted to receive downstream cable television (CATV) signals from a cable provider through the input port 528 and send copies of the downstream signals through the output ports 530a and 530b. The splitter 510 may be further adapted to receive upstream signals through ports 530a and 530b, combine the upstream signals and send them to the cable provider through port 528. The splitter housing 512 may further include a grounding element 566 to provide an electrical ground to the coaxial cable system by bonding the outer shield of a coaxial cable (not shown) to the electrical ground of the premises. The grounding element 566 may be secured by solid copper wire to either a cold water pipe or to the ground of the electrical service drop, for example. The splitter housing 512 may further include one or more attachment elements 568 to secure the splitter housing to a premises structure, for example.

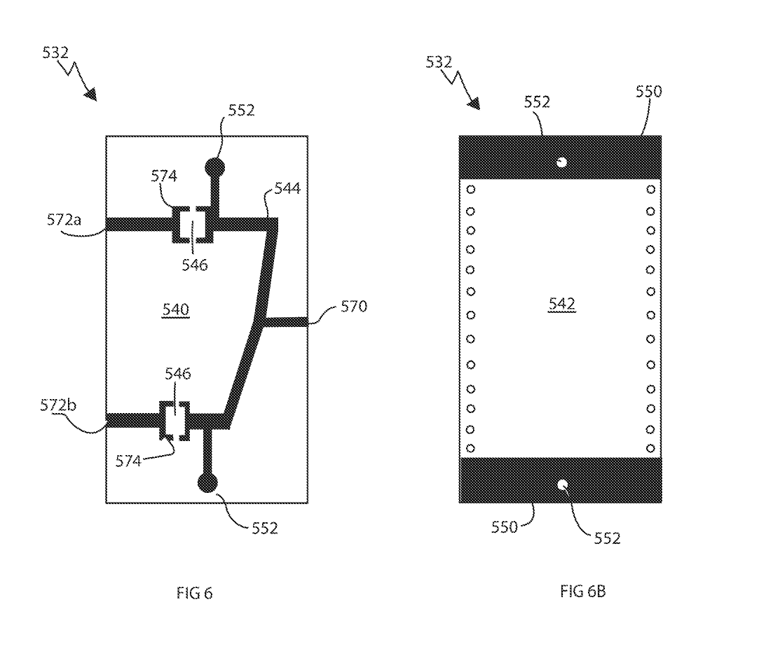

The cover 514 comprises a printed circuit board assembly 532, and may be realized by any of the embodiments disclosed herein. For purposes of illustration, the circuit board assembly 532 takes the form of the board disclosed with reference to FIG. 3, that is, a single substrate layer 538 with one or more conductive pathways (vias) 552 to provide an electrical path to the grounding element 566. FIG. 6A depicts a plan view of the first side 540 of the cover 514, and FIG. 6B depicts a plan view of the second side 542 of the cover 514. Referring to FIGS. 5, 6A, and 6B, the first side 540 of the dielectric substrate 538 includes a first conductive layer 544 realized as copper traces for the electrical signal pathways for the various electronic components on the circuit board. The copper trace 544 extends from a supplier-side port 570 to two user-side ports 572a and user-side ports 572b. The ports 570, 572a, and 572b connect to the input port 528 and output ports 530a and 530b, respectively. The circuit board assembly 532 includes surface-mounted devices 546 which, in one example, may be MoCA filters to prevent signals in a home network bandwidth (e.g., between 1125 and 1525 megahertz) from traveling upstream to the supplier-side port 570. An exemplary MoCA filter is described in commonly owned U.S. patent application Ser. No. 12/501,041, filed Jul. 10, 2009, entitled “FILTER CIRCUIT,” the entire contents of which are incorporated herein by reference. The copper trace 544 depicted in FIG. 6A is illustrative, in that other copper traces and electronic components may be present on the circuit. The surface-mounted devices 546 are mounted to conductive pads 574 on the first side 540 of the dielectric substrate 538. The conductive pads 574 are bonded or otherwise connected to the copper trace 544. The circuit board assembly 532 further includes a conductive pathway 552, realized as a via, extending through the dielectric substrate 538 from the first side 540 of the dielectric substrate 538 to the second side 542.

Turning to FIG. 6B, the opposing side of the via 552 is electrically connected or otherwise bonded to a second conductive layer 550 on the second side 542 of the dielectric substrate 538. In the illustrated embodiment, the second conductive layer 550 is a ground plane. Although not illustrated in FIG. 5, the cover 514 is advantageously sealed to the housing 512 with a bead of solder along the entire perimeter of the cover, thus providing a conductive bridge to the housing 512. The vias in the circuit board assembly 532 that are not utilized for any purpose (if present) may also be filled with solder. In this manner, an electrical ground path is provided from the surface-mounted component 546 to the conductive pad 574, then to the copper trace 544, to the via 552, to the ground plane 550, across the solder seal, to the housing 512, and finally to the grounding element 566.

In another embodiment of the present invention, the second side 542 of the cover 514 may include identifying information bonded to the substrate 538. The identifying information may take the form of alphanumeric characters 576, such as a company logo. The characters 576 can be formed of the second conductive layer 550. In one example, the entire second side 542 of the printed circuit board assembly 532 can be plated with copper, and the masking/etching operation that results in the formation of the ground plane 550 can also form the alphanumeric characters 576. This provides a durable identification or trademark.

While the present invention has been described with reference to a number of specific embodiments, it will be understood that the true spirit and scope of the invention should be determined only with respect to claims that can be supported by the present specification. Further, while in numerous cases herein wherein systems and apparatuses and methods are described as having a certain number of elements it will be understood that such systems, apparatuses and methods can be practiced with fewer than the mentioned certain number of elements. Also, while a number of particular embodiments have been described, it will be understood that features and aspects that have been described with reference to each particular embodiment can be used with each remaining particularly described embodiment.

I claim:

1. An electronics package assembly, comprising:
a housing comprising side walls and a bottom wall, the housing defining an internal cavity for placement of electronic components; and
a fluid-impermeable cover sealed to a top of the housing, the cover comprising a printed circuit board assembly having an internal side and an opposing external side, the printed circuit board assembly comprising:
a first dielectric substrate having a first side and an opposing second side;
a first conductive layer bonded to the first side of the first dielectric substrate; and
a surface-mounted electronic device electromechanically coupled to the first conductive layer, the surface-mounted device positioned within the internal cavity of the housing.

2. The electronics package assembly of claim 1, wherein the second side of the first dielectric substrate comprises the external side of the printed circuit board assembly.

3. The electronics package assembly of claim 1, wherein the printed circuit board assembly further comprises a second conductive layer bonded to the second side of the first dielectric substrate, the second conductive layer in electrical communication with the first conductive layer.

4. The electronics package assembly of claim 3, further comprising a conductive bridge from the second conductive layer to the housing.

5. The electronics package assembly of claim 4, further comprising a seal positioned between the internal cavity and the housing for sealing the fluid-impermeable cover to the top of the housing, wherein the seal comprises the conductive bridge.

6. The electronics package assembly of claim 3, further comprising a second dielectric substrate having a first side and an opposing second side, the first side of the second dielectric substrate bonded to the second conductive layer of the first dielectric substrate.

7. The electronics package assembly of claim 6, wherein the second side of the second dielectric substrate comprises the external side of the printed circuit board assembly.

8. The electronics package assembly of claim 6, wherein the second dielectric substrate comprises a third conductive layer bonded to the second side of the second dielectric substrate, the third conductive layer in electrical communication with the second conductive layer of the first dielectric substrate.

9. The electronics package assembly of claim 8, wherein the second conductive layer comprises a ground plane.

10. The electronics package assembly of claim 8, further comprising a conductive bridge from the third conductive layer to the housing.

11. The electronics package assembly of claim 10, wherein the fluid-impermeable cover is sealed to the top of the housing with a seal positioned between the internal cavity and the housing, wherein the seal comprises the conductive bridge.

12. The electronics package assembly of claim 1, wherein the external side of the printed circuit board assembly comprises a plurality of alphanumeric characters bonded to the substrate.

13. The electronics package assembly of claim 1, further comprising a conformal coating on the external side of the printed circuit board assembly.

14. A coaxial connector assembly, comprising:
an electrically conductive housing defining an internal cavity for enclosing electronic devices, the housing comprising a grounding element;
a coaxial input element coupled to the housing;
a first coaxial output element coupled to the housing;
an electrically conductive bridge coupled to the housing; and
a fluid-impermeable cover coupled to the conductive bridge, the cover comprising a printed circuit board assembly having an internal side and an opposing external side, the printed circuit board assembly comprising:
a first dielectric substrate having a first side and an opposing second side;
a first electrically conductive layer bonded to the first side of the first dielectric substrate, the first conductive layer providing a first electrically conductive pathway from the coaxial input element to the first coaxial output element, and further providing a second electrically conductive pathway to the conductive bridge; and
a surface-mounted electronic device electromechanically coupled to the first electrically conductive layer, the surface-mounted device positioned within the internal cavity of the housing.

15. The coaxial connector assembly of claim 14, wherein the electrically conductive bridge comprises a seal for protecting the internal cavity from exposure to external environmental elements.

16. The coaxial connector assembly of claim 14, wherein the connector assembly is adapted for use as a coaxial splitter, the coaxial connector assembly further comprising a second coaxial output connector coupled to the housing, the first electrically conductive layer providing an electrically conductive pathway from the coaxial input element to the first and second coaxial output elements.

17. The coaxial connector assembly of claim 14, wherein the second electrically conductive pathway to the conductive bridge is realized by a first via extending through the first dielectric substrate.

18. The coaxial connector assembly of claim 17, wherein the cover further comprises a second dielectric substrate and the second electrically conductive pathway to the conductive bridge is realized by a second via extending through the second dielectric substrate and connecting to the first via.

19. The coaxial connector assembly of claim 18, further comprising a second conductive layer bonded to the second side of the first dielectric substrate and electrically connecting the first via to the second via.

20. The coaxial connector assembly of claim 19, wherein the second conductive layer is a ground plane.

21. An electronics package assembly comprising:
a housing having an opening and defining an internal cavity; and
a printed circuit board assembly sealing and covering the opening of the housing, the printed circuit board assembly having an internal side facing the internal cavity and an opposing external side, the printed circuit board assembly including:
a dielectric substrate;
a conductive layer bonded to the dielectric substrate; and
a surface-mounted electronic device electromechanically coupled to the conductive layer, the surface-mounted device positioned within the internal cavity of the housing.
